(19) United States
(12) Patent Application Publication
(10) Pub. No.: US 2018/0366573 A1
(43) Pub. Date: Dec. 20, 2018

(54) SEMICONDUCTOR DEVICE, MEMORY DEVICE AND MANUFACTURING METHOD OF THE SAME

(71) Applicant: MACRONIX International Co., Ltd., Hsinchu (TW)

(72) Inventors: Fu-Hsing Chou, Hsinchu (TW); Yao-Fu Chan, Hsinchu (TW); Tzung-Ting Han, Hsinchu (TW)

(73) Assignee: MACRONIX International Co., Ltd., Hsinchu (TW)

(21) Appl. No.: 15/624,490

(22) Filed: Jun. 15, 2017

(51) Int. Cl. H01L 29/788; H01L 29/66; H01L 29/423

(52) U.S. Cl. CPC H01L 29/788; H01L 29/42372; H01L 29/66825

(57) ABSTRACT

A semiconductor device, a memory device, and a manufacturing method of the same are provided. The memory device includes a substrate, a floating gate, a gate insulation layer, an inter-gate dielectric layer, and a control gate. The control gate is a multi-layer structure with three or more layers, and at least one layer of the multi-layer structure is a metal silicide layer.

### BACKGROUND OF THE INVENTION

### 1. Field of the Invention

The invention relates to a semiconductor technology. More particularly, the invention relates to a semiconductor device, a memory device and a manufacturing method of the same.

### 2. Description of Related Art

Owing to advantages such as capabilities of performing multiple data storing, reading, and erasing and retaining stored data after power supply is cut off, the non-volatile memory has become a memory device that has been widely adopted by personal computers and electronic equipment.

A word line in the non-volatile memory is a metal silicide layer formed on a control gate most of the time. After the metal silicide layer is formed, thermal treatment is usually applied to the metal silicide layer in order to remove impurities in the metal silicide layer. Nevertheless, metal silicide in the metal silicide layer may diffuse into the control gate caused by the thermal treatment process. Moreover, metal silicide may even be in touch with an inter-gate dielectric layer (IPD), leading to problems such as capacitor failure of the IPD, a reduction in breakdown voltage of the IPD, and decreasing device reliability.

FIG. 1 is a transmission electron microscope (TEM) image of a conventional memory device.

Referring to FIG. 1, a memory device includes a substrate 100, an isolation structure 102 in the substrate 100, a floating gate 104, a gate insulation layer 106, an IPD 108, and a control gate 110. The control gate 110 is generally a multi-layer structure and includes a first layer 1101 filled in the floating gate 104 and a second layer 1102 on the first layer 1101, wherein the first layer 1101 is polysilicon and the second layer 1102 is metal silicide. In the memory device illustrated in FIG. 1, the metal silicide of the second layer 1102 may diffuse into the first layer 1101 caused by thermal treatment. Moreover, at the circled part, metal silicide is even in touch with the IPD 108, problems thus occur such as capacitor failure of the IPD 108, a reduction in breakdown voltage of the IPD 108, and decreasing device reliability.

### SUMMARY OF THE INVENTION

The invention provides a semiconductor device, a memory device and a manufacturing method of the same for preventing metal silicide in a metal silicide layer from being in touch with an inter-gate dielectric layer (IPD), and thus the semiconductor device may maintain favorable reliability.

The semiconductor device of the invention includes a first conductive layer, an IPD, and a second conductive layer. The first conductive layer is located on a substrate. The IPD is located on the first conductive layer. The second conductive layer is located on the IPD and is a multi-layer structure with three or more layers, wherein at least one layer of the multi-layer structure is a metal silicide layer.

In an embodiment of the invention, the multi-layer structure includes a first layer, a second layer, and a third layer. The second layer is located between the first layer and the third layer.

In an embodiment of the invention, a thickness of the first layer and a thickness of the second layer both are less than a thickness of the third layer.

In an embodiment of the invention, a grain size of the first layer is less than a grain size of the second layer and less than a grain size of the third layer.

In an embodiment of the invention, at least one layer of the multi-layer structure is made of carbon-doped polysilicon.

In an embodiment of the invention, grain sizes of layers in the multi-layer structure are different.

In an embodiment of the invention, thicknesses of the layers in the multi-layer structure are different.

The memory device of the invention includes a floating gate, a gate insulation layer, an IPD, and a control gate. The floating gate is located on a substrate. The gate insulation layer is located between the floating gate and the substrate. The IPD is located on the floating gate. The control gate is located on the IPD and is a multi-layer structure with three or more layers, wherein at least one layer of the multi-layer structure is a metal silicide layer.

In another embodiment of the invention, the control gate includes a first layer, a second layer, and a third layer. The second layer is located between the first layer and the third layer.

In another embodiment of the invention, in the control gate, a thickness of the first layer and a thickness of the second layer both are less than a thickness of the third layer.

In another embodiment of the invention, in the control gate, a grain size of the first layer is less than a grain size of the second layer and less than a grain size of the third layer.

In another embodiment of the invention, at least one layer of the control gate is made of carbon-doped polysilicon.

In another embodiment of the invention, grain sizes of layers in the control gate are different.

In another embodiment of the invention, thicknesses of the layers in the control gate are different.

The manufacturing method of a memory device of the invention is provided. In the manufacturing method, a gate insulation layer and a floating gate are formed sequentially on a substrate. The floating gate and the gate insulation layer are patterned. A plurality of isolation structures is formed in the substrate. A surface of the isolation structures is lower than a surface of the floating gate. An IPD is formed on the floating gate and the isolation structures. A control gate is formed on the IPD, the control gate is a multi-layer structure with three or more layers, and at least one layer of the multi-layer structure is a metal silicide layer.

In still another embodiment of the invention, the control gate is formed by forming a first layer, a second layer, and a third layer sequentially on the IPD.

In still another embodiment of the invention, carbon may be doped during forming the first layer.

In still another embodiment of the invention, carbon may be doped during forming the second layer.

In still another embodiment of the invention, a thermal treatment may be performed after the metal silicide layer is formed.

In view of the foregoing, in the embodiments of the invention, the multi-layer structure with three or more layers is adopted as the control gate of the memory device. Since the control gate can prevent the IPD from being in touch with the metal silicide caused by diffusing during the thermal treatment, the reliability of semiconductor device maybe improved.

To make the above features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a transmission electron microscope (TEM) image of a conventional memory device.

FIG. 2A to FIG. 2H are schematic cross-sectional views illustrating a manufacturing process of a memory device according to an embodiment of the invention.

FIG. 3 is a TEM image of a memory device in an example.

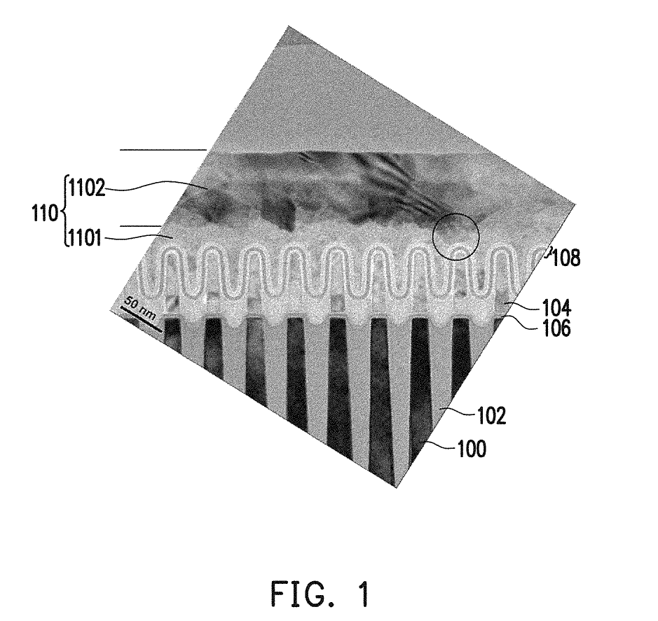

### DESCRIPTION OF THE EMBODIMENTS

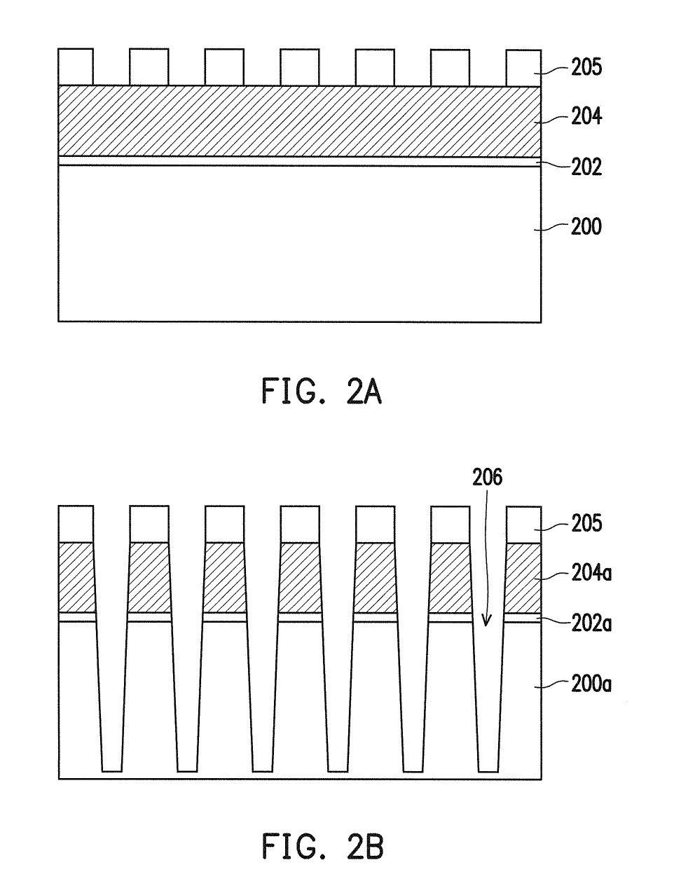

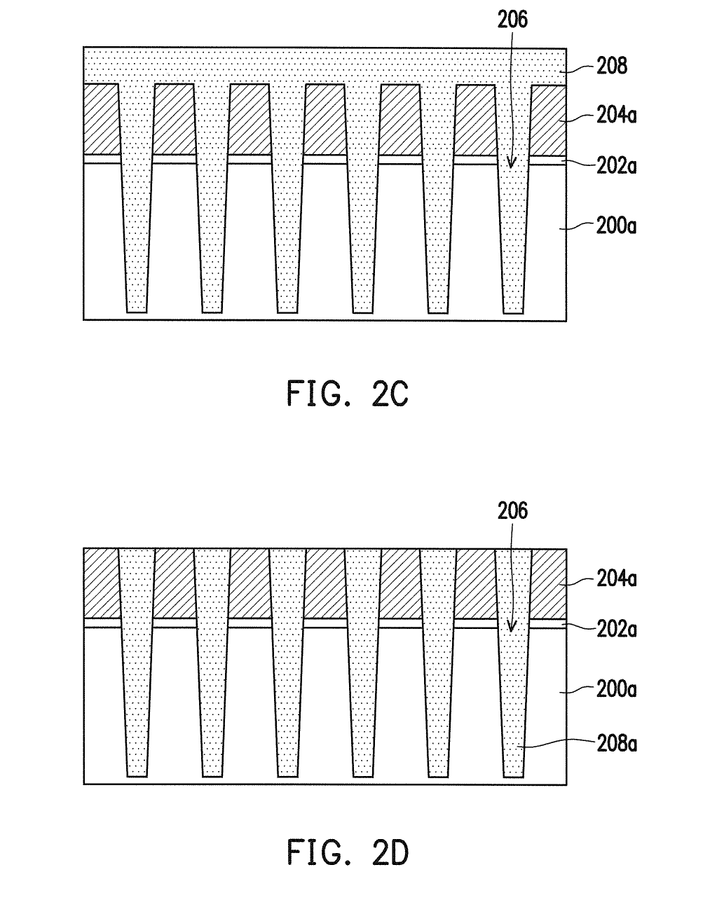

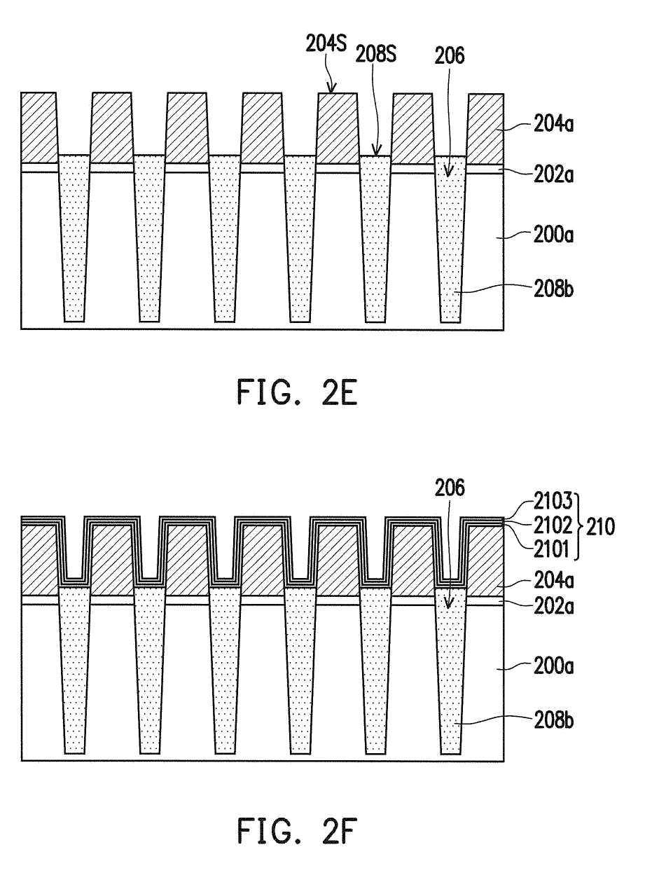

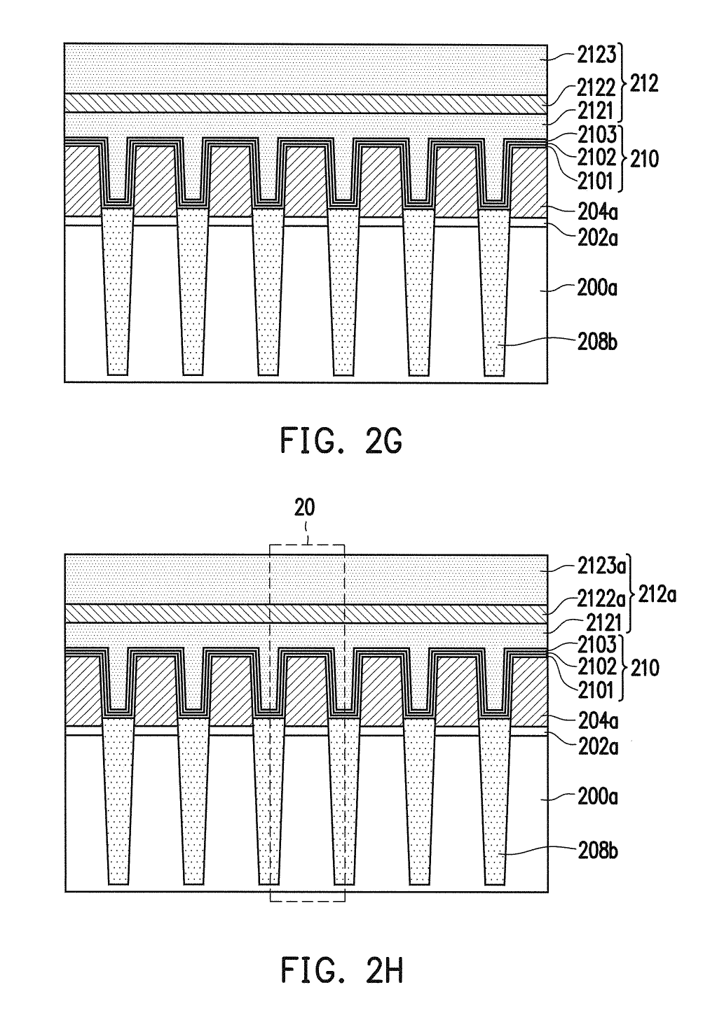

FIG. 2A to FIG. 2H are schematic cross-sectional views illustrating a manufacturing process of a memory device according to an embodiment of the invention.

Referring to FIG. 2A, a gate insulation layer 202 is formed on a substrate 200. In the embodiment, the substrate 200 is, for example, a semiconductor substrate, a semiconductor compound substrate, or a silicon on insulator (SOI) substrate. The semiconductor is IVA group atoms, such as silicon or germanium, for example. The semiconductor compound is formed of IVA group atoms, such as silicon carbide or silicon germanium, or formed of IIIA group atoms and VA group atoms, such as gallium arsenide, for example. The substrate 200 may be doped, and the dopant in the substrate 200 may be P type or N type. The P type dopant may be IIIA group ions, such as boron ions. The N type dopant may be VA group ions, such as arsenic or phosphorus.

In the embodiment, the gate insulation layer 202 may be formed of a single material layer. The single material layer is a low dielectric constant material or a high dielectric constant material, for example. The low dielectric constant material is a dielectric material having a dielectric constant smaller than 4, such as silicon oxide or silicon oxynitride. The high dielectric constant material is a dielectric material having a dielectric constant greater than 4, such as HfAlO, HfO₂, Al₂O₃, or Si₃N₄, for example. The gate insulation layer 202 may also selectively be a double-layer stack structure or a multi-layer stack structure in which injection current may be increased according to the band-gap engineering (BE) theory. The double-layer stack structure is &allied of a low dielectric constant material and a high dielectric constant material (represented by low dielectric constant material/high dielectric constant material), such as silicon oxide/HfSiO, silicon oxide/HfO₂ or silicon oxide/silicon nitride, for example. The multi-layer stack structure is formed of a low dielectric constant material, a high dielectric constant material, and a low dielectric constant material (represented by low dielectric constant material/high dielectric constant material/low dielectric constant material), such as silicon oxide/silicon nitride/silicon oxide or silicon oxide/Al₂O₃/silicon oxide, for example. A method of forming the gate insulation layer 202 is, for example, a thermal oxidation method or a chemical vapor deposition method.

Referring to FIG. 2A again, a conductive layer 204 is formed on the gate insulation layer 202. A material of the conductive layer 204 is, for example, polysilicon (including doped polysilicon), polycide, or a stack layer, a metal layer, or an applicable conductor of a combination thereof. A method of forming the conductive layer 204 is, for example, a chemical vapor deposition method or a physical vapor deposition method. After that, a patterned mask layer 205 is formed on the conductive layer 204. The patterned mask layer 205 may be a single material layer or a double material layer. In an embodiment, the patterned mask layer 205 is, for example, a patterned photoresist layer.

Then, referring to FIG. 2B, an etching process is performed on the conductive layer 204 and the gate insulation layer 202 to pattern them and form a floating gate 204a and a gate insulation layer 202a in which the patterned mask layer 205 is employed as the mask. Afterwards, a plurality of trenches 206 are formed in the substrate 200a by another etching process. The above etching processes are anisotropic etching, such as dry etching, for example.

Next, referring to FIG. 2C, the patterned mask layer 205 is removed and an insulation material layer 208 is formed on the substrate 200a. As such, the trenches 206 are filled with and the floating gate 204a is covered by insulation materials. The method of removing the patterned mask layer 205 is, for example, a dry removing method, a wet removing method, or a combination thereof. A material of the insulation material layer 208 is, for example, silicon oxide or borophosphosilicate glass. A method of forming the insulation material layer 208 is, for example, a chemical vapor deposition method.

Next, referring to FIG. 2D, the insulation material layer 208 on the floating gate 204a is removed, and an insulation material layer 208a located in the trenches 206 are formed. A method of removing the insulation material layer 208 may be performed by adopting the chemical mechanical polishing (CMP) process, but the invention is not limited thereto. In another embodiment, the wet etching method may also be adopted.

Then, referring to FIG. 2E, a portion of the insulation material layer 208a in the trenches 206 is removed to form an isolation structure 208b. A surface 208s of the isolation structure 208b is lower than a surface 204s of the floating gate 204a. A method of removing a portion of the insulation material layer 208a is, for example, the wet etching method or the dry etching method.

Then, referring to FIG. 2F, an inter-gate dielectric layer (IPD) 210 is formed on the floating gate 204a and the isolation structure 208b. The IPD 210 may be formed by a single layer or by multilayers such as ONO structure. In the embodiment, the IPD 210 is exemplified as a three-layer structure, wherein the IPD 210 includes the dielectric layer 2101, the dielectric layer 2102 and the dielectric layer 2103. The dielectric layer 2103 is located above the dielectric layer 2102, and the dielectric layer 2102 is located above the dielectric layer 2101. A material of the dielectric layer 2101 and the dielectric layer 2103 is, for example, silicon oxide or other insulation material. A method of forming the dielectric layer 2101 and the dielectric layer 2103 is, for example, the chemical vapor deposition method or the thermal oxidation method. A material of the dielectric layer 2102 is, for example, silicon nitride or other insulation material. A method of forming the dielectric layer 2102 is, for example, the chemical vapor deposition method or the thermal nitrification method.

Next, referring to FIG. 2G, a stacked structure 212 is formed on the IPD 210. The stacked structure 212 is a polysilicon structure with three or more layers. In the embodiment, the stacked structure 212 is formed by forming a first layer 2121, a second material layer 2122, and a third material layer 2123 sequentially on the IPD 210, and the method of forming above three layers 2121, 2122 and 2123 includes, for example, the chemical vapor deposition process or the physical vapor deposition process. Then, the three layers 2121, 2122, and 2123 are patterned to form the stacked structure 212.

In another embodiment of the invention, carbon may be doped during forming the first layer 2121. As such, a grain size of the first layer 2121 is controlled at 10 nm to 20 nm, and thus the first layer 2121 may be filled in a space between the floating gate 204a smoothly. In another embodiment of the invention, carbon may also be doped during forming the second material layer 2122. Thereby, at least one of the first layer 2121 and the second material layer 2122 is a carbon-doped polysilicon layer, and that a grain size of polysilicon of at least one of the first layer 2121 and the second material layer 2122 may be reduced. A blocking capability to metal silicide may also be enhanced.

In another embodiment of the invention, grain sizes of layers in the stacked structure 212 are different. As the grain sizes of the layers in the stacked structure 212 are different, the capability to block metal silicide may thus be enhanced. In an embodiment of the invention, a grain size of the first layer 2121 is less than a grain size of the second material layer 2122 and less than a grain size of the third material layer 2123.

In an embodiment of the invention, thicknesses of layers in the stacked structure 212 are different, wherein the thicknesses of the first layer 2121 is 200 Å to 400 Å for example, the thicknesses of the second material layer 2122 is 100 Å to 300 Å for example, and the thicknesses of the third material layer 2123 is 400 Å to 600 Å for example. When the thicknesses of the layers in the stacked structure 212 is controlled within the range, metal silicide may be prevented from being in touch with the IPD and a thickness of the control gate may be maintained at the same time. As such, the control gate may not be excessively thick, and problems such as uneven thickness or non-uniform etching of the control gate may thereby further be prevented.

In another embodiment of the invention, the thicknesses of the layers in the stacked structure 212 are different. As the thicknesses of the layers in the stacked structure 212 are different, grain sizes of polysilicon of the layers in the stacked structure 212 may further be controlled. As the grain sizes of polysilicon of the layers in the stacked structure 212 are different, the capability to block metal silicide may thus be enhanced. In an embodiment of the invention, a thickness of the first layer 2121 and a thickness of the second material layer 2122 are less than a thickness of the third material layer 2123.

In the embodiments of the invention, the stacked structure 212 is exemplified to be formed with three polysilicon layers, but the invention is not limited thereto. The limitation for the stacked structure is formed as a multi-layer structure with three or more layers, and hence the stacked structure may be for lied with four or more layers.

After that, referring to FIG. 2H, a metal layer (not shown) such as cobalt or nickel which can form metal silicide is deposited on the stacked structure 212. A method of forming the metal layer is, for example, the chemical vapor deposition method or the physical vapor deposition method. A thermal treatment is performed after the metal layer is deposited, and the metal layer will react with the second material layer 2122 and the third material layer 2123 to form a second layer 2122a and a third layer 2123a resulting in the formation of a control gate 212a. A material of the second layer 2122a and the third layer 2123a is, for example, cobalt silicide (CoSi₂), nickel silicide, or other applicable materials. In an embodiment of the invention, the second layer 2122a and the third layer 2123a is made of CoSi₂. In an embodiment of the invention, the thermal treatment is a rapid thermal process (RTP). In the embodiment, the control gate 212a is formed as a multi-layer structure with three or more layers. As such, metal silicide in the second layer 2122a and the third layer 2123a is prevented from being in touch with the IPD 210 when diffusing caused by thermal treatment in the subsequent manufacturing process. Moreover, the semiconductor device may maintain favorable reliability.

After the second layer 2122a and the third layer 2123a are formed, another thermal treatment may further be performed. The thermal treatment is performed under a temperature ranges from 800° C. to 900° C. for 60 s to 120 s to remove impurities or undesired substances in the IPD layer such as silicon oxide or silicon nitride

Referring to FIG. 2H again, the memory device provided by the embodiments of the invention includes the floating gate 204a, the gate insulation layer 202a, the isolation structure 208b, the dielectric layer 2101, the dielectric layer 2102, the dielectric layer 2103, and the control gate 212a.

A material of the floating gate 204a is, for example, polysilicon (including doped polysilicon), polycide, or a stack layer, a metal layer, or an applicable conductor of a combination thereof.

The gate insulation layer 202a may be formed of a single material layer. The single material layer is a low dielectric constant material or a high dielectric constant material, for example. The gate insulation layer 202a is located between the floating gate 204a and the substrate 200. The gate insulation layer 202a may also selectively be a double-layer stack structure or a multi-layer stack structure in which injection current may be increased according to the BE theory.

The isolation structure 208b is configured to isolate two adjacent memory devices 20. A material of the isolation structure 208b may be an insulation material, for example, silicon oxide or borophosphosilicate glass. The isolation structure 208b is located in the substrate 200 between two adjacent floating gates 204a.

The IPD 210 may include the dielectric layer 2101, the dielectric layer 2102 and the dielectric layer 2103. A material of the dielectric layer 2101 and the dielectric layer 2103 is, for example, silicon oxide or other insulation materials. A material of the dielectric layer 2102 is, for example, silicon nitride or other insulation materials.

The control gate 212a covers the floating gates 204a of the memory devices 20 and covers the isolation structure 208b isolating two adjacent memory devices 20. The control gate 212a includes the first layer 2121, the second layer 2122a, and the third layer 2123a. The second layer 2122a is located between the first layer 2121 and the third layer 2123a, wherein the first layer 2121 is made of polysilicon, and the second layer 2122a and the third layer 2123a are made of metal silicide. In another embodiment, the first layer 2121 may be made of carbon-doped polysilicon. In addition, in an embodiment, the grain sizes of the layers in the control gate 212a may be different. For instance, the grain size of the first layer 2121 may be less than the grain size of the second layer 2122a and less than the grain size of the third layer 2123a. In another embodiment, the thicknesses of the layers in the control gate 212a are different. For instance, the thickness of the first layer 2121 and the thickness of the second layer 2122a may be less than the thickness of the third layer 2123a. The material of the second layer 2122a and the third layer 2123a is, for example, CoSi₂, NiSi, or other applicable materials. In an embodiment of the invention, the second layer 2122a and the third layer 2123a are made of CoSi₂.

In the embodiments, the control gate 212a with a three-layer structure is exemplified, but the invention is not limited thereto. The control gate may have four or more layers. The control gate 212a is a multi-layer structure with three or more layers. As such, the control gate 212a can prevent the IPD 210 from being in touch with metal silicide in the second layer 2122a and the third layer 2123a caused by diffusing during the thermal treatment. Moreover, the semiconductor device may maintain favorable reliability.

In other embodiments, a semiconductor device provided by the embodiments of the invention includes a first conductive layer, an IPD, and a second conductive layer. The first conductive layer is located on a substrate. The IPD is located on the first conductive layer. The second conductive layer is located on the IPD and is a multi-layer structure with three or more layers, wherein at least one layer of the multi-layer structure is a metal silicide layer.

In the semiconductor device provided by the embodiments of the invention, the multi-layer structure includes a first layer, a second layer, and a third layer. The second layer is located between the first layer and the third layer.

In the semiconductor device provided by the embodiments of the invention, a thickness of the first layer and a thickness of the second layer both are less than a thickness of the third layer.

In the semiconductor device provided by the embodiments of the invention, a grain size of the first layer may be less than a grain size of the second layer and less than a grain size of the third layer.

In the semiconductor device provided by the embodiments of the invention, at least one layer in the multi-layer structure is made of carbon-doped polysilicon.

In the semiconductor device provided by the embodiments of the invention, grain sizes of layers in the multi-layer structure are different.

In the semiconductor device provided by the embodiments of the invention, thicknesses of the layers in the multi-layer structure are different.

An example is listed below to prove the effect of the invention, but the invention is not limited thereto.

### EXAMPLE

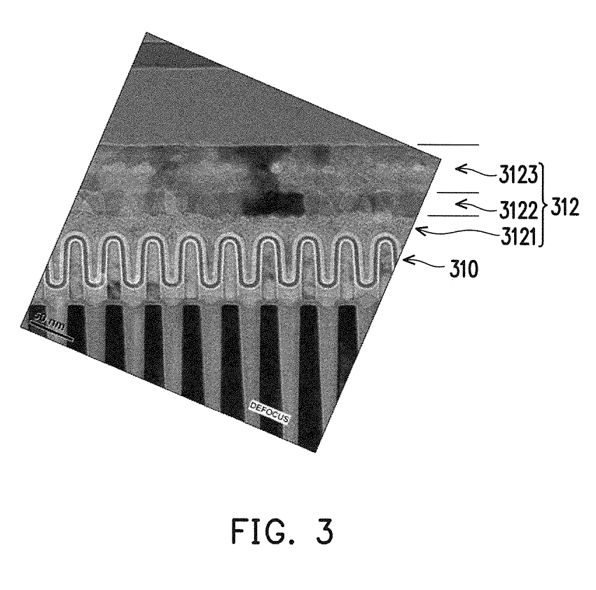

A memory device as shown in FIG. 2H is to be manufactured. A rapid thermal process (RTP) is performed under 850° C. for two minutes, and then a structure is observed as presented in FIG. 3. In the control gate 312 formed on an IDP 310, a thickness of the first layer 3121 is 300 Å, a thickness of the second layer 3122 is 200 Å, and a thickness of the third layer 3123 is 500 Å; and a grain size of the first layer 3121 is 15 nm to 20 nm, a grain size of the second layer 3122 is 10 nm to 20 nm, and a grain size of the third layer 3123 is 30 nm to 40 nm. The second layer 3122 and the third layer 3123 are made of CoSi₂.

FIG. 3 is a TEM image of the memory device in the example.

Referring to FIG. 3, in the example, metal silicide in the second layer 3122 and the third layer 3123 is not in touch with the IPD 310. As such, problems such as capacitor failure of the IPD 310, a reduction in breakdown voltage of the IPD 310, and decreasing device reliability may be avoided.

To sum up, in the embodiments of the invention, the conductive layer using the multi-layer structure with three or more layers are adopted as the gate structure and may be applied in a variety of semiconductor devices, for example, acting as the control gate of the memory device. As such, it is possible to prevent the metal silicide layer from diffusion and contacting with the IPD due to thermal treatment, thereby improving the reliability of the semiconductor device. In addition, the fabricating process of the invention can be integrated with the existing processes.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

1. A semiconductor device, comprising:
a first conductive layer, located on a substrate;
an inter-gate dielectric layer (IPD), located on the first conductive layer; and
a second conductive layer, located on the IPD, the second conductive layer comprises a first layer, a second layer, and a third layer, and the second layer is located between the first layer and the third layer, wherein a grain size of the first layer is controlled at 10 nm to 20 nm, the first layer is made of polysilicon, and the second layer and the third layer are made of metal silicide.

2. (canceled)

3. The semiconductor device as claimed in claim 1, wherein a thickness of the first layer and a thickness of the second layer are less than a thickness of the third layer.

4. The semiconductor device as claimed in claim 1, wherein a grain size of the first layer is less than a grain size of the second layer and a grain size of the third layer.

5. The semiconductor device as claimed in claim 1, wherein the first layer is made of carbon-doped polysilicon.

6. The semiconductor device as claimed in claim 1, wherein grain sizes of the first layer, the second layer, and the third layer are different.

7. The semiconductor device as claimed in claim 1, wherein thicknesses of the first layer, the second layer, and the third layer are different.

8. A memory device, comprising:
a floating gate, located on a substrate;
a gate insulation layer, located between the floating gate and the substrate;
an inter-gate dielectric layer (IPD), located on the floating gate; and
a control gate, located on the IPD, the control gate comprises a first layer, a second layer, and a third layer, and the second layer is located between the first layer and the third layer, wherein a grain size of the first layer is controlled at 10 nm to 20 nm, the first layer is made of polysilicon, and the second layer and the third layer are made of metal silicide.

9. (canceled)

10. The memory device as claimed in claim 8, wherein a thickness of the first layer of the control gate and a thickness of the second layer of the control gate are less than a thickness of the third layer of the control gate.

11. The memory device as claimed in claim 8, wherein a grain size of the first layer of the control gate is less than a grain size of the second layer of the control gate and a grain size of the third layer of the control gate.

12. The memory device as claimed in claim 8, wherein the first layer of the control gate is made of carbon-doped polysilicon.

13. The memory device as claimed in claim 8, wherein grain sizes of the first layer, the second layer, and the third layer of the control gate are different.

14. The memory device as claimed in claim 8, wherein thicknesses of the first layer, the second layer, and the third layer of the control gate are different.

15. A manufacturing method of a memory device, comprising:
forming a gate insulation layer and a floating gate sequentially on a substrate;
patterning the floating gate and the gate insulation layer;
forming a plurality of isolation structures on the substrate, wherein a surface of the isolation structures is lower than a surface of the floating gate;
forming an inter-gate dielectric layer (IPD) on the floating gate and the isolation structures; and
forming a control gate on the IPD, wherein a method of forming the control gate comprises: forming a first layer, a second layer, and a third layer sequentially on the IPD, a grain size of the first layer is controlled at 10 nm to 20 nm, the first layer is made of polysilicon, and the second layer and the third layer are made of metal silicide.

16. (canceled)

17. The manufacturing method of the memory device as claimed in claim 15, further comprising doping carbon during forming the first layer.

18. (canceled)

19. The manufacturing method of the memory device as claimed in claim 15, further comprising performing a thermal treatment after forming the third layer.
